(19) United States
(12) Patent Application Publication
(10) Pub. No.: US 2024/0038726 A1
(43) Pub. Date: Feb. 1, 2024

(54) AI MODULE

(71) Applicant: Panasonic Intellectual Property Management Co., Ltd., Osaka (JP)

(72) Inventors: Koji OBATA, Osaka (JP); Masaru SASAGO, Osaka (JP); Masamichi NAKAGAWA, Osaka (JP); Tatsuya KABE, Osaka (JP); Hiroyuki GOMYO, Kyoto (JP); Masatomo MITSUHASHI, Osaka (JP); Yutaka SONODA, Tokyo (JP)

(21) Appl. No.: 18/264,194

(22) PCT Filed: Dec. 21, 2021
(86) PCT No.: PCT/JP2021/047358

§ 371 Date: Aug. 3, 2023

(30) Foreign Application Priority Data
Feb. 10, 2021 (JP) 2021-019828

(51) Int. Cl. H01L 25/065; H01L 23/48; H01L 23/00; H01L 27/02; H10B 80/00

(52) U.S. Cl. CPC H01L 25/0657; H01L 23/481; H01L 24/32; H01L 24/48; H01L 24/73; H01L 24/16; H01L 27/0207; H01L 24/08; H10B 80/00; H01L 2225/0651; H01L 2225/06513; H01L 2225/06524; H01L 2225/06544; H01L 2924/1431; H01L 2924/1434; H01L 2224/16146; H01L 2224/48225; H01L 2224/32225; H01L 2224/73207; H01L 2224/73253; H01L 2224/73265; H01L 2224/08145

(57) ABSTRACT

An AI module includes a first semiconductor chip. The first semiconductor chip includes a plurality of operation blocks each of which performs a predetermined operation and a plurality of memory blocks each including memory. The plurality of operation blocks and the plurality of memory blocks are arranged in a checkered pattern or in a striped pattern in plan view.

### CROSS-REFERENCE OF RELATED APPLICATIONS

This application is the U.S. National Phase under 35 U.S.C. § 371 of International Patent Application No. PCT/JP2021/047358, filed on Dec. 21, 2021, which in turn claims the benefit of Japanese Patent Application No. 2021-019828, filed on Feb. 10, 2021, the entire disclosures of which Applications are incorporated by reference herein.

### TECHNICAL FIELD

The present disclosure relates to AI modules.

### BACKGROUND ART

Patent Literature (PTL) 1 discloses a multi-layer semiconductor stack, which is a stack of multiple semiconductor dies that include functional units such as processor cores.

### CITATION LIST

### Patent Literature

[PTL 1] Japanese Unexamined Patent Application Publication No. 2010-263203

### Non Patent Literature

[NPL 1] M. Saito et. al., “An Extended XY Coil for Noise Reduction in Inductive-Coupling Link”, 2009 IEEE Asian Solid-State Circuits Conference, Dec. 2009, pp. 305-308
[NPL 2] K. Niitsu et al., “Interference from Power/Signal Lines and to SRAM Circuits in 65 nm CMOS Inductive-Coupling Link”, 2007 IEEE Asian Solid-State Circuits Conference, Jan. 2007, pp. 131-134

### SUMMARY OF INVENTION

### Technical Problem

In recent years, a variety of operations based on artificial intelligence (AI) are expected to be performed with low power consumption. In a case where the multi-layer semiconductor stack disclosed in PTL 1 is used to perform such operations, the travel distance for data between the functional units needs to be long, preventing a reduction in power consumption.

The present disclosure provides an AI module capable of performing AI-based operations with low power consumption.

### Solution to Problem

An AI module according to one aspect of the present disclosure includes a first semiconductor chip. The first semiconductor chip includes a plurality of first processing units each of which performs a predetermined operation and a plurality of second processing units each including memory. The plurality of first processing units and the plurality of second processing units are arranged in a checkered pattern or in a striped pattern in plan view.

### Advantageous Effects of Invention

According to the present disclosure, AI-based operations can be performed with low power consumption.

### BRIEF DESCRIPTION OF DRAWINGS

FIG. 1 is a perspective view of a general appearance of an AI module according to an embodiment.

FIG. 2 is a cross-sectional view of the AI module according to the embodiment.

FIG. 3A is a plan view of a layout of a base chip in the AI module according to the embodiment.

FIG. 3B is a plan view of a layout of a first semiconductor chip and a third semiconductor chip in the AI module according to the embodiment.

FIG. 3C is a plan view of a layout of a second semiconductor chip and a fourth semiconductor chip in the AI module according to the embodiment.

FIG. 4 is a cross-sectional view of a stacked state of the four semiconductor chips in the AI module according to the embodiment.

FIG. 5 is a cross-sectional view of connecting parts of through vias for power supply in the AI module according to the embodiment.

FIG. 6 is a flowchart of a production method for the AI module according to the embodiment.

FIG. 7 is a plan view of layouts of a base chip and semiconductor chips in an AI module according to Variation 1 of the embodiment.

FIG. 8 is a plan view of layouts of a base chip and semiconductor chips in an AI module according to Variation 2 of the embodiment.

FIG. 9 is a cross-sectional view of a stacked state of four semiconductor chips in the AI module according to Variation 2 of the embodiment.

FIG. 10 is a plan view of layouts of a base chip and semiconductor chips in an AI module according to Variation 3 of the embodiment.

FIG. 11 is a cross-sectional view of a stacked state of four semiconductor chips in the AI module according to Variation 3 of the embodiment.

FIG. 12 is a plan view of layouts of a base chip and semiconductor chips in an AI module according to Variation 4 of the embodiment.

FIG. 13 is a cross-sectional view of an AI module according to Variation 5 of the embodiment.

FIG. 14 is a cross-sectional view of an AI module according to Variation 6 of the embodiment.

### DESCRIPTION OF EMBODIMENTS

### Overview of the Present Disclosure

An AI module according to one aspect of the present disclosure includes a first semiconductor chip. The first semiconductor chip includes a plurality of first processing units each of which performs a predetermined operation and a plurality of second processing units each including memory. The plurality of first processing units and the plurality of second processing units are arranged in a checkered pattern or in a striped pattern in plan view.

With this arrangement, the first processing units that perform the operations and the second processing units that include the memory are disposed next to each other in one semiconductor chip, and thus the lengths of wires connecting the first processing units and the second processing units are reduced. This reduces the travel distance for data between the first processing units and the second processing units and thus reduces the power consumption.

Moreover, for example, each of the plurality of first processing units may perform the operation based on a machine learning model.

This improves the accuracy of AI-based operations.

Moreover, for example, an AI module according to one aspect of the present disclosure may further include a second semiconductor chip stacked on the first semiconductor chip. The second semiconductor chip may include a plurality of third processing units each of which performs a predetermined operation and a plurality of fourth processing units each including memory. The plurality of third processing units and the plurality of fourth processing units may be arranged in a checkered pattern or in a striped pattern in plan view.

Thus, stacking two semiconductor chips can increase the amount of operations and the amount of memory. As a result, the operations can be performed at high speed.

Moreover, for example, each of the plurality of third processing units may perform the operation based on a machine learning model.

This improves the accuracy of AI-based operations.

Moreover, for example, the first semiconductor chip may further include a first communication unit, and the second semiconductor chip may further include a second communication unit that communicates with the first communication unit.

This allows direct data transmission and reception between the semiconductor chips.

Use of TSVs (Through Silicon Vias) is a known technology for communication between semiconductor chips. However, to use TSVs, regions for through vias need to be allocated in semiconductor substrates. In addition, processing units need to be protected from static electricity (ESD: Electro-Static Discharge). This increases the areas of regions other than the regions in which the first processing units and the second processing units are provided (that is, the active regions), preventing a reduction in the size of the semiconductor chips.

In contrast, in an AI module according to one aspect of the present disclosure, for example, the first communication unit and the second communication unit each may include an antenna having a coil shape. Moreover, for example, the first communication unit and the second communication unit may communicate with each other through the antennas thereof being inductively coupled.

In this manner, a technology for wireless communication between stacked semiconductor chips can be implemented through near-field inductive coupling using coiled antennas. Since no TSVs are used, the areas of regions other than the active regions can be reduced. This reduces the size of the semiconductor chips, that is, the size of the AI module. Note that, in a case where a reduction in the size of the semiconductor chips is not required, TSVs may be used in the communication units.

In a case where near-field inductive coupling communication is used, certain restrictions are imposed on wiring patterns between coiled antennas. For example, in a case where metal wires or the like are interposed between two antennas, the metal wires prevent inductive coupling and reduce communication accuracy.

In contrast, in an AI module according to one aspect of the present disclosure, for example, the plurality of first processing units may correspond one-to-one with the plurality of third processing units and may overlap the corresponding third processing units in plan view, and the plurality of second processing units may correspond one-to-one with the plurality of fourth processing units and may overlap the corresponding fourth processing units in plan view. For example, the first communication unit may overlap one of the plurality of second processing units in plan view, or the second communication unit may overlap one of the plurality of fourth processing units in plan view.

Memory is formed by repeatedly placing a predetermined pattern including wiring and storage portions. Accordingly, the restrictions for the use of near-field inductive coupling communication can be easily met by, for example, removing the pattern only from parts overlapping the coiled antennas. In the AI module according to this aspect, for example, the second processing units, the fourth processing units, and the coiled antennas overlap each other in plan view. Thus, near-field inductive coupling communication can be used without allocating dedicated regions to the antennas. This reduces the size and the power consumption of the semiconductor chips.

Moreover, in a case where a plurality of semiconductor chips are stacked, heat generated during operation needs to be efficiently dissipated. In contrast, in an AI module according to one aspect of the present disclosure, for example, the plurality of first processing units may correspond one-to-one with the plurality of fourth processing units and may overlap the corresponding fourth processing units in plan view, and the plurality of second processing units may correspond one-to-one with the plurality of third processing units and may overlap the corresponding third processing units in plan view.

The first processing units and the third processing units that perform the operations generate more heat than the second processing units and the fourth processing units that include the memory. In the AI module according to this aspect, the first processing units and the third processing units do not overlap each other in plan view. This prevents local heat concentration and allows efficient heat dissipation.

Moreover, for example, the first semiconductor chip may further include one or more fifth processing units each including memory, and the second semiconductor chip may further include one or more sixth processing units each including memory. The one or more fifth processing units may correspond one-to-one with the one or more sixth processing units and may overlap the corresponding sixth processing units in plan view. Moreover, for example, the first communication unit may overlap one of the one or more fifth processing units in plan view, and the second communication unit may overlap one of the one or more sixth processing units in plan view.

With this arrangement, the fifth processing units, the sixth processing units, and the coiled antennas overlap each other in plan view, and thus near-field inductive coupling communication can be used without allocating dedicated regions to the antennas. This reduces the size and the power consumption of the semiconductor chips.

Moreover, for example, the first semiconductor chip may further include a first semiconductor substrate including a first main surface and a second main surface that face opposite directions, and the plurality of first processing units and the plurality of second processing units may be disposed at positions closer to the first main surface of the first semiconductor substrate than to the second main surface. The second semiconductor chip may further include a second semiconductor substrate including a third main surface and a fourth main surface that face opposite directions, and the plurality of third processing units and the plurality of fourth processing units may be disposed at positions closer to the third main surface of the second semiconductor substrate than to the fourth main surface. The first semiconductor chip and the second semiconductor chip may be stacked such that the first main surface and the third main surface face each other.

Thus, the AI modules according to the above-described aspects can be formed by, for example, stacking two semiconductor chips having an identical configuration such that the top main surfaces face each other. That is, only one type of semiconductor chips needs to be prepared, contributing to design simplification and cost reduction.

Moreover, for example, an AI module according to an aspect of the present disclosure may further include a third semiconductor chip stacked on the second semiconductor chip and a fourth semiconductor chip stacked on the third semiconductor chip. The third semiconductor chip may include a third semiconductor substrate including a fifth main surface and a sixth main surface that face opposite directions, a plurality of seventh processing units each of which performs a predetermined operation, and a plurality of eighth processing units each including memory. The plurality of seventh processing units and the plurality of eighth processing units may be disposed at positions closer to the fifth main surface of the third semiconductor substrate than to the sixth main surface, and may be arranged in a checkered pattern or in a striped pattern in plan view. The fourth semiconductor chip may include a fourth semiconductor substrate including a seventh main surface and an eighth main surface that face opposite directions, a plurality of ninth processing units each of which performs a predetermined operation, and a plurality of tenth processing units each including memory. The plurality of ninth processing units and the plurality of tenth processing units may be disposed at positions closer to the seventh main surface of the fourth semiconductor substrate than to the eighth main surface, and may be arranged in a checkered pattern or in a striped pattern in plan view. The third semiconductor chip and the fourth semiconductor chip may be stacked such that the fifth main surface and the seventh main surface face each other, and the second semiconductor chip and the third semiconductor chip may be stacked such that the fourth main surface and the sixth main surface face each other.

Thus, the amount of operations and the amount of memory can be further increased by, for example, preparing a plurality of stacks of two semiconductor chips of which the top main surfaces joined together and then by stacking the stacks such that the bottom main surfaces face each other. Also in this case, only one type of semiconductor chips needs to be prepared, contributing to design simplification and cost reduction.

Moreover, for example, an AI module according to one aspect of the present disclosure may further include a through via, for supplying power to the second semiconductor chip, passing through the first semiconductor chip.

This allows sufficient power voltage to be supplied to the semiconductor chips.

Hereinafter, embodiments will be described in detail with reference to the drawings.

Note that each of the embodiments described below illustrates a general or specific example. The numerical values, shapes, materials, elements, positions and connections of the elements, steps, order of steps, and the like shown in the following embodiments are mere examples and are not intended to limit any aspect of the present disclosure. Moreover, among the elements in the following embodiments, those that are not recited in any of the independent claims are described as optional elements.

Moreover, each drawing is a schematic diagram and is not necessarily illustrated in precise dimensions. Thus, for example, the drawings are not necessarily drawn on the same scale. Moreover, substantially identical configurations are given the same reference signs throughout the drawings, and duplicate explanations are omitted or simplified.

Moreover, in this description, terms that indicate the relationships between elements such as being perpendicular or coincident and that indicate the shapes of elements such as square or rectangular and numerical ranges are not expressions representing exact meanings only, but are expressions meaning that substantially equivalent ranges, for example, differences of about several percent, are also included.

Moreover, in this description, terms “upward” and “downward” do not refer to an upward direction (vertically upward) and downward direction (vertically downward), respectively, in an absolute space recognition, but are used as terms defined by relative positional relationships on the basis of the stacking order in a multilayer configuration. Moreover, terms “above” and “below” are used to describe not only a situation where two elements are spaced with another element therebetween, but also a situation where two elements are in close contact with each other. In the following embodiments, a side on which semiconductor chips are stacked with respect to a base chip is defined as “upper side”, and the opposite side is defined as “lower side”.

Moreover, in this description, unless otherwise noted, the use of ordinal numbers, such as “first” and “second”, is to avoid confusion among elements of the same kind and to distinguish respective elements rather than to denote the number or the order of those elements.

### Embodiment

### 1. Overview

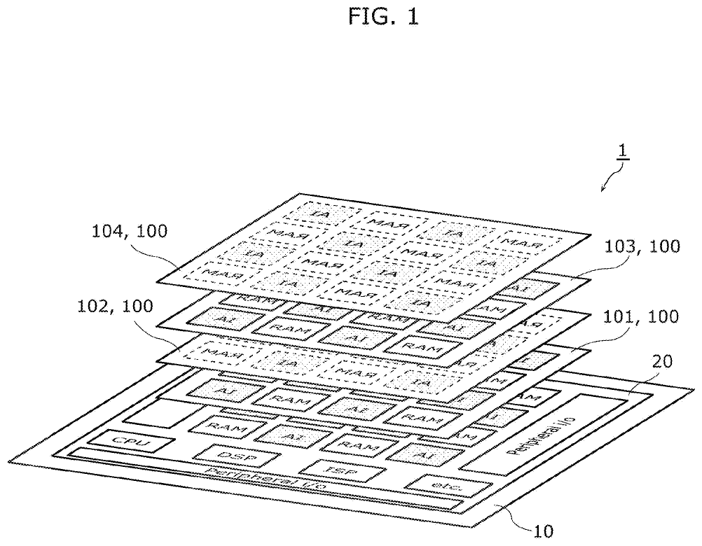

First, the overview of an AI module according to an embodiment will be described with reference to FIG. 1. FIG. 1 is a perspective view of a general appearance of AI module 1 according to this embodiment.

AI module 1 illustrated in FIG. 1 is a device that performs AI-based operations. The AI-based operations include, for example, natural language processing, speech recognition, image recognition, and recommendations, and processes of controlling various devices. The operations are performed on the basis of, for example, machine learning or deep learning.

As illustrated in FIG. 1, AI module 1 includes interposer 10, base chip 20, and one or more semiconductor chips 100. In this embodiment, one or more semiconductor chips 100 in AI module 1 include first semiconductor chip 101, second semiconductor chip 102, third semiconductor chip 103, and fourth semiconductor chip 104.

Interposer 10, base chip 20, and one or more semiconductor chips 100 are stacked in stated order. Note that FIG. 1 schematically illustrates the positional relationships between the elements only and does not illustrate, for example, the thicknesses of the elements. Moreover, although one or more semiconductor chips 100 are not in contact with each other in the drawing, one or more semiconductor chips 100 adjacent to each other are in direct contact with each other in practice. Alternatively, members (for example, insulating films) may be interposed between one or more semiconductor chips 100, and semiconductor chips 100 may be in contact with the members.

Interposer 10 is a relay part that relays electrical connection between base chip 20 and substrates (not illustrated).

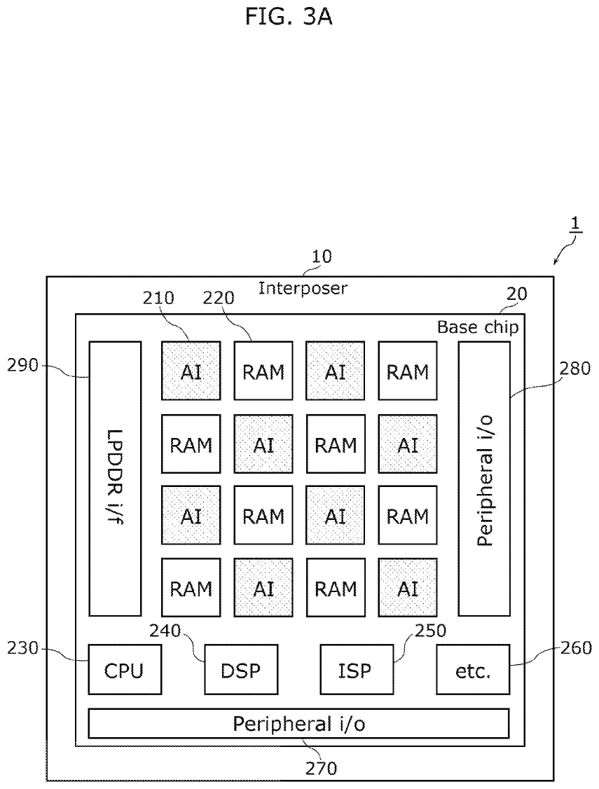

Base chip 20 is a SoC (System on a Chip) supported by interposer 10. A specific configuration of base chip 20 will be described later with reference to FIG. 3A.

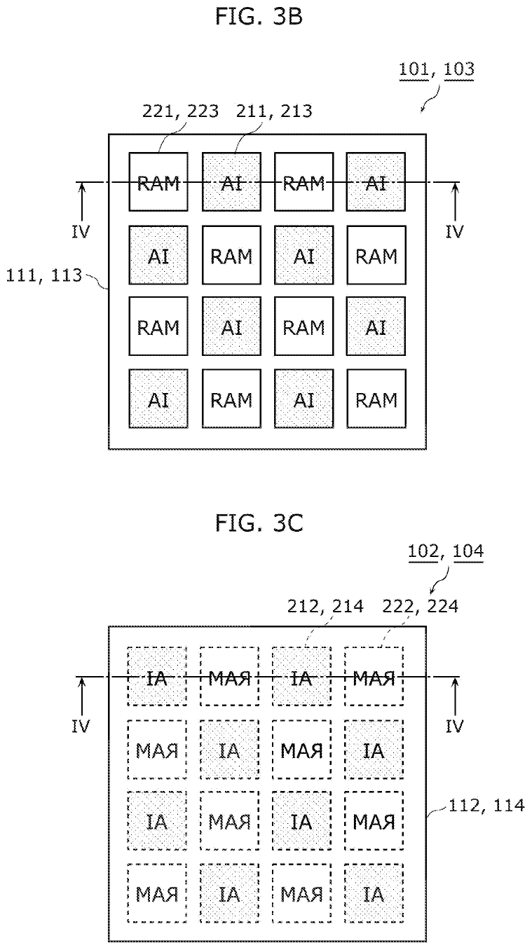

Each of one or more semiconductor chips 100 includes a processing unit that performs AI-based operations and a processing unit that includes memory for storing, for example, programs or data required for operations or operational results. Semiconductor chips 100 are also referred to as dies. Specific configurations of one or more semiconductor chips 100 will be described later with reference to FIGS. 3B, 3C, and 4.

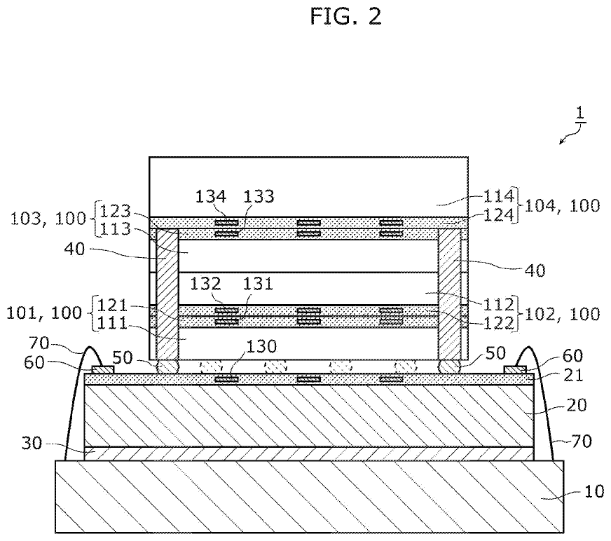

FIG. 2 is a cross-sectional view of AI module 1 according to this embodiment. Note that, for ease of viewing, hatch patterns, which represent cross-sections, are not provided for semiconductor substrates in the cross-sectional view illustrated in FIG. 2. The same applies to other cross-sectional views described later.

As illustrated in FIG. 2, AI module 1 further includes DAF (Die Attach Film) 30, a plurality of through vias 40, a plurality of bump electrodes 50, a plurality of bonding pads 60, and a plurality of bonding wires 70. Note that the number of through vias 40, bump electrodes 50, bonding pads 60, or bonding wires 70 may be one.

DAF 30 is an adhesive film that bonds interposer 10 and base chip 20.

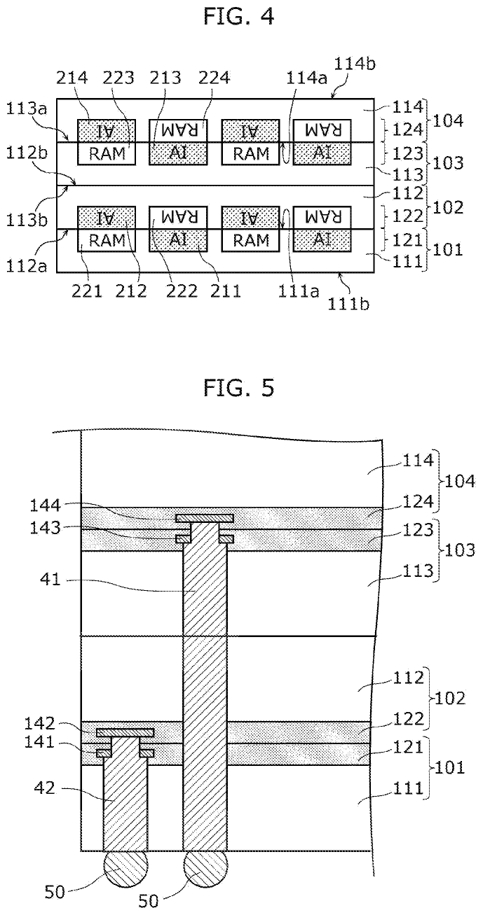

Through vias 40 are vias for supplying power to one or more semiconductor chips 100. Through vias 40 pass through at least one of one or more semiconductor chips 100. A specific example of through vias 40 will be described later with reference to FIG. 5.

Bump electrodes 50 are connected to through vias 40. Bump electrodes 50 are made of, for example, metal such as gold or alloy such as solder. In addition to supplying power to one or more semiconductor chips 100 through through vias 40, bump electrodes 50 support and secure one or more semiconductor chips 100. The plurality of bump electrodes 50 may include those mainly having the function of supporting and securing semiconductor chips 100 without the function of supplying power. Note that an insulating resin member may be provided for the space between base chip 20 and first semiconductor chip 101 such that spaces between the plurality of bump electrodes 50 are filled with the resin member.

Bonding pads 60 are conductive terminals disposed on a main surface of base chip 20 and are connected to bonding wires 70. Bonding pads 60 are parts of a wiring pattern formed using, for example, metal such as gold, copper, or aluminum or alloy.

Bonding wires 70 are conductive wires that electrically connect interposer 10 and base chip 20. Bonding wires 70 are metal wires formed using, for example, metal such as gold, copper, or aluminum or alloy. Bonding wires 70 are used to supply power to base chip 20 and one or more semiconductor chips 100 or to transmit and receive data to and from base chip 20 and one or more semiconductor chips 100.

### 2. Base Chip

Next, an example configuration of base chip 20 will be described with reference to FIG. 3A. FIG. 3A is a plan view of a layout of base chip 20 in AI module 1 according to this embodiment.

As illustrated in FIG. 3A, base chip 20 includes a plurality of operation blocks 210 and a plurality of memory blocks 220. The plurality of operation blocks 210 and the plurality of memory blocks 220 are arranged in a checkered pattern in plan view.

Each of the plurality of operation blocks 210 is an example of a processing unit that performs predetermined operations. The predetermined operations include AI-based operations. The predetermined operations may include logical operations other than those based on AI. That is, at least one of the plurality of operation blocks 210 is an AI accelerator circuit that performs AI-based operations. For example, operation blocks 210 perform at least one of convolution operation, matrix operation, or pooling operation. Operation blocks 210 perform operations on the basis of a machine learning model.

Operation blocks 210 may include logarithmic processing circuits. The logarithmic processing circuits perform operations on logarithmically quantized input data. Specifically, the logarithmic processing circuits perform convolution operation on logarithmically quantized input data. Multiplication included in the convolution operation can be performed by addition by converting data to be subjected to the operation into the logarithmic domain. This allows AI-based operations to be performed at higher speed.

Moreover, the operations performed by operation blocks 210 may include error diffusion using dithering. Specifically, operation blocks 210 may include dither circuits. The dither circuits perform operations using error diffusion. This eliminates or minimizes degradation of computational accuracy even with a small number of bits.

One or more operation blocks 210 of the plurality of operation blocks 210 may be operation circuits that perform logical operation.

Each of the plurality of memory blocks 220 includes memory. Memory blocks 220 include, for example, SRAM (Static Random Access Memory). Memory blocks 220 store data used for operations performed by operation blocks 210 and/or operational results. Note that the memory included in memory blocks 220 may be DRAM (Dynamic Random Access Memory) or may be NAND flash memory.

Moreover, as illustrated in FIG. 3A, base chip 20 includes CPU (Central Processing Unit) 230, DSP (Digital Signal Processor) 240, ISP (Image Signal Processor) 250, functional circuit 260, peripheral input/output interfaces 270 and 280, and memory interface 290. Note that base chip 20 does not need to include at least one of these elements. Moreover, the arrangements of the elements are not limited to the example illustrated in FIG. 3A.

CPU 230 is a processor that controls overall AI module 1. Specifically, CPU 230 transmits and receives data and signals between base chip 20 and one or more semiconductor chips 100 to perform operations and to execute commands.

DSP 240 is a processor that performs digital signal processing related to AI-based operations.

ISP 250 is a signal processing circuit that processes image signals and video signals.

Functional circuit 260 is a circuit that implements predetermined functions performed by AI module 1.

Peripheral input/output interfaces 270 and 280 are interfaces that transmit and receive data and signals to and from devices other than AI module 1. For example, peripheral input/output interface 270 is, but not limited to, a QSPI (Quad Serial Peripheral Interface), GPIO (General Purpose Input/Output), or a debug interface. Moreover, peripheral input/output interface 280 is, but not limited to, an MIPI (Mobile Industry Processor Interface) or a PCIe (Peripheral Component Interconnect-Express).

Memory interface 290 is an interface for DRAM provided outside AI module 1. For example, memory interface 290 is, but not limited to, an interface compliant with the LPDDR (Low Power Double Data Rate) standard.

The elements illustrated in FIG. 3A are disposed in active region 21 illustrated in FIG. 2. Active region 21 includes one of two main surfaces of the semiconductor substrate that constitutes base chip 20.

### 3. Semiconductor Chips

Next, configurations of semiconductor chips 100 will be described.

In this embodiment, the plurality of semiconductor chips 100 include first semiconductor chip 101, second semiconductor chip 102, third semiconductor chip 103, and fourth semiconductor chip 104. First semiconductor chip 101, second semiconductor chip 102, third semiconductor chip 103, and fourth semiconductor chip 104 are stacked above base chip 20 in stated order.

FIG. 3B is a plan view of a layout of first semiconductor chip 101 and third semiconductor chip 103 in AI module 1 according to this embodiment. FIG. 3C is a plan view of a layout of second semiconductor chip 102 and fourth semiconductor chip 104 in AI module 1 according to this embodiment. FIGS. 3B and 3C each illustrate a plan layout of the semiconductor chips, stacked over base chip 20, viewed from above.

FIG. 4 is a cross-sectional view of a stacked state of the four semiconductor chips in AI module 1 according to the embodiment. Specifically, FIG. 4 illustrates the stacked state of first semiconductor chip 101, second semiconductor chip 102, third semiconductor chip 103, and fourth semiconductor chip 104.

As illustrated in FIGS. 3B and 4, first semiconductor chip 101 includes a plurality of operation blocks 211 and a plurality of memory blocks 221. Operation blocks 211 are an example of first processing units that perform predetermined operations such as AI-based operations. Operation blocks 211 are, for example, identical to operation blocks 210 and perform the operations on the basis of the machine learning model. Memory blocks 221 are an example of second processing units including memory. Memory blocks 221 are, for example, identical to memory blocks 220 and include SRAM.

Moreover, as illustrated in FIG. 4, first semiconductor chip 101 includes first semiconductor substrate 111 and first active region 121.

First semiconductor substrate 111 includes top main surface 111a and bottom main surface 111b facing opposite directions. Top main surface 111a is an example of a first main surface. Bottom main surface 111b is an example of a second main surface. First semiconductor substrate 111 is, for example, a silicon substrate.

First active region 121 is a region in which the plurality of operation blocks 211 and the plurality of memory blocks 221 are disposed. Specifically, first active region 121 includes top main surface 111a. That is, the plurality of operation blocks 211 and the plurality of memory blocks 221 are disposed at positions closer to top main surface 111a than to bottom main surface 111b. Note that the “active region” is an operating region in which the principal function of the semiconductor chip is exercised. A plurality of circuit elements, such as transistors, capacitors, inductors, and resistors or diodes, are formed in the active region. The plurality of circuit elements form the operation blocks and the memory blocks by being electrically connected with wires.

As illustrated in FIGS. 3C and 4, second semiconductor chip 102 includes a plurality of operation blocks 212 and a plurality of memory blocks 222. Operation blocks 212 are an example of third processing units that perform predetermined operations such as AI-based operations. Operation blocks 212 are, for example, identical to operation blocks 211 and perform the operations on the basis of the machine learning model. Memory blocks 222 are an example of fourth processing units including memory. Memory blocks 222 are, for example, identical to memory blocks 221 and include SRAM.

Moreover, as illustrated in FIG. 4, second semiconductor chip 102 includes second semiconductor substrate 112 and second active region 122.

Second semiconductor substrate 112 includes top main surface 112a and bottom main surface 112b facing opposite directions. Top main surface 112a is an example of a third main surface. Bottom main surface 112b is an example of a fourth main surface. Second semiconductor substrate 112 is, for example, a silicon substrate.

Second active region 122 is a region in which the plurality of operation blocks 212 and the plurality of memory blocks 222 are disposed. Specifically, second active region 122 includes top main surface 112a. That is, the plurality of operation blocks 212 and the plurality of memory blocks 222 are disposed at positions closer to top main surface 112a than to bottom main surface 112b.

As illustrated in FIGS. 3B and 4, third semiconductor chip 103 includes a plurality of operation blocks 213 and a plurality of memory blocks 223. Operation blocks 213 are an example of seventh processing units that perform predetermined operations such as AI-based operations. Operation blocks 213 are, for example, identical to operation blocks 211 and perform the operations on the basis of the machine learning model. Memory blocks 223 are an example of eighth processing units including memory. Memory blocks 223 are, for example, identical to memory blocks 221 and include SRAM.

Moreover, as illustrated in FIG. 4, third semiconductor chip 103 includes third semiconductor substrate 113 and third active region 123.

Third semiconductor substrate 113 includes top main surface 113a and bottom main surface 113b facing opposite directions. Top main surface 113a is an example of a fifth main surface. Bottom main surface 113b is an example of a sixth main surface. Third semiconductor substrate 113 is, for example, a silicon substrate.

Third active region 123 is a region in which the plurality of operation blocks 213 and the plurality of memory blocks 223 are disposed. Specifically, third active region 123 includes top main surface 113a. That is, the plurality of operation blocks 213 and the plurality of memory blocks 223 are disposed at positions closer to top main surface 113a than to bottom main surface 113b.

As illustrated in FIGS. 3C and 4, fourth semiconductor chip 104 includes a plurality of operation blocks 214 and a plurality of memory blocks 224. Operation blocks 214 are an example of ninth processing units that perform predetermined operations such as AI-based operations. Operation blocks 214 are, for example, identical to operation blocks 211 and perform the operations on the basis of the machine learning model. Memory blocks 224 are an example of tenth processing units including memory. Memory blocks 224 are, for example, identical to memory blocks 221 and include SRAM.

Moreover, as illustrated in FIG. 4, fourth semiconductor chip 104 includes fourth semiconductor substrate 114 and fourth active region 124.

Fourth semiconductor substrate 114 includes top main surface 114a and bottom main surface 114b facing opposite directions. Top main surface 114a is an example of a seventh main surface. Bottom main surface 114b is an example of an eighth main surface. Fourth semiconductor substrate 114 is, for example, a silicon substrate.

Fourth active region 124 is a region in which the plurality of operation blocks 214 and the plurality of memory blocks 224 are disposed. Specifically, fourth active region 124 includes top main surface 114a. That is, the plurality of operation blocks 214 and the plurality of memory blocks 224 are disposed at positions closer to top main surface 114a than to bottom main surface 114b.

As illustrated in FIG. 3B, first semiconductor chip 101 and third semiconductor chip 103 have the same layout. For example, in first semiconductor chip 101, the plurality of operation blocks 211 and the plurality of memory blocks 221 are arranged in a checkered pattern (including “in a matrix” or “in a grid” as a synonym) in plan view. Specifically, operation blocks 211 and memory blocks 221 are alternately arranged both in a row direction (horizontal direction) and in a column direction (vertical direction). Note that sets of multiple operation blocks 211 and sets of multiple memory blocks 221 may be alternately arranged in at least one of the row direction or the column direction.

As illustrated in FIG. 3C, second semiconductor chip 102 and fourth semiconductor chip 104 have the same layout. For example, in second semiconductor chip 102, the plurality of operation blocks 212 and the plurality of memory blocks 222 are arranged in a checkered pattern (including “in a matrix” or “in a grid” as a synonym) in plan view. Note that the arrangement of operation blocks 210 and memory blocks 220 included in base chip 20 is the same as the arrangement of operation blocks 212 and memory blocks 222 included in second semiconductor chip 102.

In this embodiment, the plurality of operation blocks 211 of first semiconductor chip 101 correspond one-to-one with the plurality of memory blocks 222 of second semiconductor chip 102 and are superposed on corresponding memory blocks 222 in plan view. Similarly, the plurality of memory blocks 221 of first semiconductor chip 101 correspond one-to-one with the plurality of operation blocks 212 of second semiconductor chip 102 and are superposed on corresponding operation blocks 212 in plan view. In other words, in plan view, the operation blocks and the memory blocks are not superposed on the other operation blocks and the other memory blocks, respectively.

Similarly, in third semiconductor chip 103 and fourth semiconductor chip 104, the operation blocks of one chip are superposed on the memory blocks of the other chip in plan view, and the operation blocks and the memory blocks are not superposed on the other operation blocks and the other memory blocks, respectively. Similarly, in third semiconductor chip 103 and second semiconductor chip 102, the operation blocks of one chip are superposed on the memory blocks of the other chip in plan view, and the operation blocks and the memory blocks are not superposed on the other operation blocks and the other memory blocks, respectively. Similarly, in base chip 20 and first semiconductor chip 101, the operation blocks of one chip are superposed on the memory blocks of the other chip in plan view, and the operation blocks and the memory blocks are not superposed on the other operation blocks and the other memory blocks, respectively.

In this embodiment, second semiconductor chip 102 and fourth semiconductor chip 104 have a configuration obtained by turning over first semiconductor chip 101 (or third semiconductor chip 103). That is, as illustrated in FIG. 4, first semiconductor chip 101 and second semiconductor chip 102 are stacked such that respective top main surfaces 111a and 112a face each other. This facilitates the superposition of the operation blocks of one chip on the memory blocks of the other chip in plan view and prevents the operation blocks and the memory blocks from being superposed on the other operation blocks and the other memory blocks, respectively.

Similarly, third semiconductor chip 103 and fourth semiconductor chip 104 are stacked such that respective top main surfaces 113a and 114a face each other. Moreover, second semiconductor chip 102 and third semiconductor chip 103 are stacked such that respective bottom main surfaces 112b and 113b face each other.

In accordance with AI module 1 according to this embodiment, the plurality of semiconductor chips 100 stacked in this manner can increase the computing power and the amount of memory. Moreover, the operation blocks and the memory blocks are close to each other in semiconductor chips 100 and base chip 20, reducing the travel distance for data and thus reducing the power consumption.

Moreover, in two adjacent semiconductor chips 100 out of the plurality of stacked semiconductor chips 100, the operation blocks of one chip are superposed on the memory blocks of the other chip. That is, the operation blocks, which easily generate heat, are not superposed on the other operation blocks. This prevents local heat concentration and allows efficient heat dissipation.

### 4. Communications Between Semiconductor Chips

Next, communications between semiconductor chips 100 will be described with reference to FIG. 2.

In AI module 1, base chip 20 and the plurality of semiconductor chips 100 each include a communication unit for transmitting and receiving data and signals to and from each other. In this embodiment, communications are conducted through near-field inductive coupling communication. Specifically, base chip 20 and the plurality of semiconductor chips 100 each include an antenna that can be inductively coupled with other antennas.

As illustrated in FIG. 2, coiled antenna 130 is disposed in active region 21 of base chip 20. Moreover, coiled antenna 131 is disposed in first active region 121 of first semiconductor chip 101. Coiled antenna 132 is disposed in second active region 122 of second semiconductor chip 102. Coiled antenna 133 is disposed in third active region 123 of third semiconductor chip 103. Coiled antenna 134 is disposed in fourth active region 124 of fourth semiconductor chip 104. Note that, although not illustrated, a communication control circuit for wireless communication is disposed in each active region.

Antennas 130 to 134 can communicate with each other by being inductively coupled. Specifically, antennas 130 to 134 are superposed on each other in plan view. For example, antennas 130 to 134 are disposed to have a common coil axis. Antennas 130 to 134 are, for example, pattern antennas formed in the respective active regions with metal wires to have a coil shape.

The thicknesses of first semiconductor substrate 111, second semiconductor substrate 112, and third semiconductor substrate 113 are, for example, 15 μm. Moreover, the thickness of fourth semiconductor substrate 114 is, for example, 100 μm. The distance between bottom main surface 111b of first semiconductor substrate 111 and the top main surface of base chip 20 (height of bump electrodes 50) is, for example, 20 μm. Accordingly, the distance between antenna 130 of base chip 20 and farthest antenna 134 of fourth semiconductor chip 104 is about 65 μm, which is a distance in a range allowing near-field inductive coupling communication. Note that the dimensions are only one example and are not limited in particular.

### 5. Power Supply

Next, power supply to semiconductor chips 100 will be described with reference to FIG. 5.

FIG. 5 is a cross-sectional view of connecting parts of the through vias for power supply in AI module 1 according to this embodiment. FIG. 5 illustrates two through vias 41 and 42.

Through via 41 is used to supply power to third semiconductor chip 103 and fourth semiconductor chip 104, and is identical to through vias 40 illustrated in FIG. 2. Through via 41 is a so-called TSV. Through via 41 is made of conductive polysilicon or a metal material such as copper.

Through via 41 is connected to terminal 143 disposed in third active region 123 and terminal 144 disposed in fourth active region 124. Terminals 143 and 144 are parts of wiring patterns formed using, for example, metal such as gold, copper, or aluminum or alloy. Power is supplied to the operation blocks and the memory blocks through terminals 143 and 144.

Through via 42 is used to supply power to first semiconductor chip 101 and second semiconductor chip 102. Through via 42 is a so-called TSV. Through via 42 is made of conductive polysilicon or a metal material such as copper.

Through via 42 is connected to terminal 141 disposed in first active region 121 and terminal 142 disposed in second active region 122. Terminals 141 and 142 are parts of wiring patterns formed using, for example, metal such as gold, copper, or aluminum or alloy. Power is supplied to the operation blocks and the memory blocks through terminals 141 and 142.

In this manner, through via 41 for third semiconductor chip 103 and fourth semiconductor chip 104 and through via 42 for first semiconductor chip 101 and second semiconductor chip 102 are separately provided. This allows power to be supplied to the semiconductor chips with sufficient accuracy.

Note that two through vias 41 and 42 of different lengths are used in this embodiment, although not limited thereto. Through via 42 does not need to be provided, and through via 41 may also be connected to terminals 141 and 142. In this case, terminals 141 to 144 are superposed on each other in plan view.

### 6. Production Method

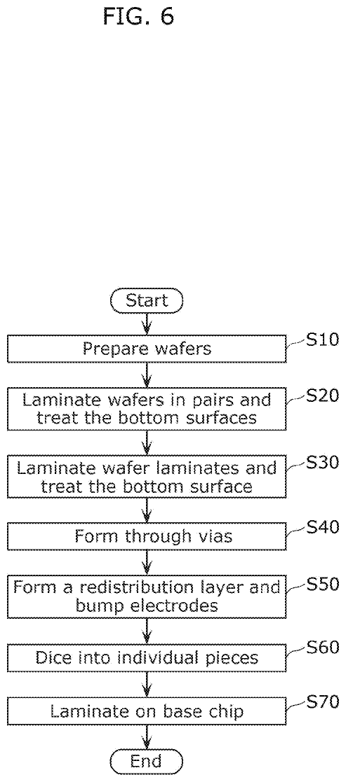

Next, a production method for AI module 1 will be described with reference to FIG. 6.

FIG. 6 is a flowchart of the production method for AI module 1 according to this embodiment.

As illustrated in FIG. 6, first, a plurality of (herein four) semiconductor wafers with the plurality of operation blocks and the plurality of memory blocks are prepared (S10). Note that the operation blocks and the memory blocks can be formed by, for example, a semiconductor process such as a CMOS process.

Next, the four prepared semiconductor wafers are stacked in pairs such that the top main surfaces of two semiconductor wafers face each other, and then the bottom main surface of one semiconductor wafer of each pair is ground and insulated (S20). The grinding process includes, for example, at least one of back grinding (BG) or CMP (Chemical Mechanical Polishing). The insulating process includes, for example, deposition of insulating films such as silicon dioxide films.

Next, the stacks of the two semiconductor wafers are stacked such that the ground and insulated bottom main surfaces face each other, and then the bottom main surface of one stack (the uppermost surface or the lowermost surface) is ground and insulated (S30). This forms a stack including the four semiconductor wafers that correspond to first semiconductor chip 101, second semiconductor chip 102, third semiconductor chip 103, and fourth semiconductor chip 104.

Next, through vias 40 are formed (S40). Specifically, parts of the semiconductor wafers are removed by etching so that through-holes are created. Subsequently, the inner surfaces of the through-holes are protected with insulating films, and then the through-holes are filled with a conductive material. This forms through vias 40.

Next, a redistribution layer and then bump electrodes 50 are formed on bottom main surface 111b of first semiconductor chip 101 (S50).

Next, the stack of the semiconductor wafers is diced into individual pieces (S60). This forms a plurality of stacks of first semiconductor chip 101, second semiconductor chip 102, third semiconductor chip 103, and fourth semiconductor chip 104. Note that the surface without the redistribution layer may be ground before dicing.

Next, a diced stack is stacked on base chip 20 (S70). In this manner, AI module 1 illustrated in FIG. 2 is produced. Note that the production method described herein is only one example and is not limited in particular.

### 7. Variations

Next, variations of AI module 1 according to the embodiment will be described. Variations 1 to 4 differ from the embodiment in the layout of operation blocks and memory blocks. Variations 5 and 6 differ from the embodiment in the number of stacked semiconductor chips. In the description below, differences from the embodiment will be mainly described, and explanations of points in common will be omitted or simplified.

### 7-1. Variation 1

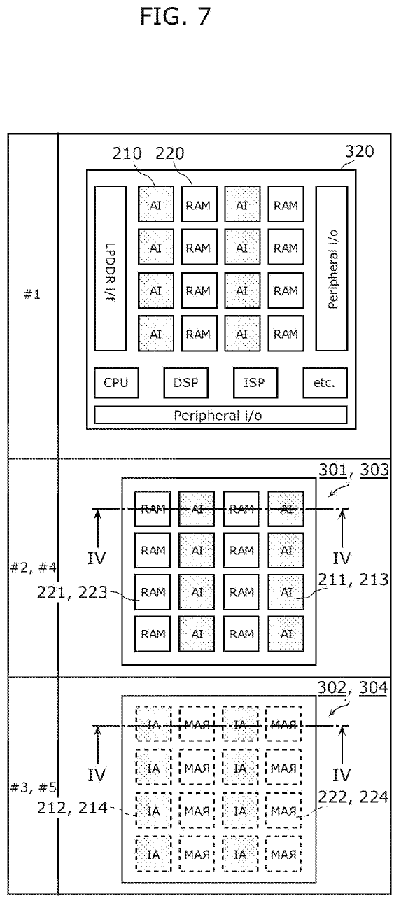

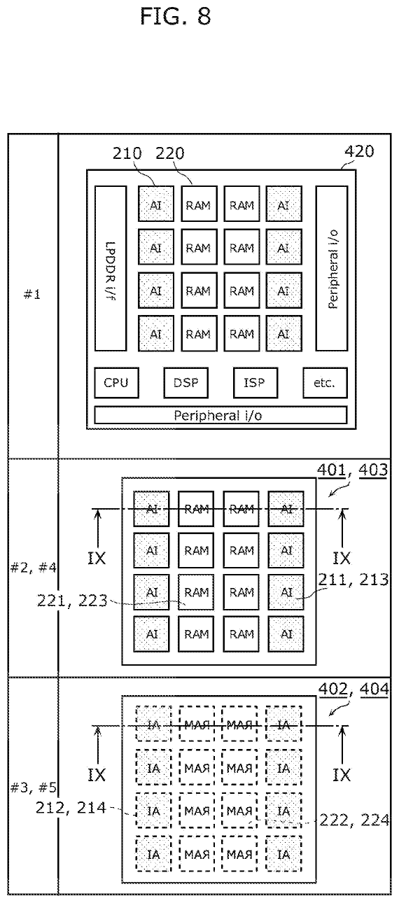

First, Variation 1 will be described with reference to FIG. 7. FIG. 7 is a plan view of layouts of base chip 320 and semiconductor chips in an AI module according to this variation. Note that “#1” in FIG. 7 indicates a first layer of operation blocks and memory blocks (that is, the base chip). “#2” to “#5” indicate the stacking orders of the semiconductor chips relative to the base chip serving as the first layer. The same applies to FIGS. 8, 10, and 12 described later.

As illustrated in FIG. 7, a plurality of operation blocks and a plurality of memory blocks are arranged in a striped pattern in base chip 320, first semiconductor chip 301, second semiconductor chip 302, third semiconductor chip 303, and fourth semiconductor chip 304.

Specifically, the operation blocks and the memory blocks are alternately arranged in the row direction. The operation blocks and the memory blocks are arranged such that the same types of blocks are aligned consecutively in the column direction. Note that sets of multiple operation blocks and sets of multiple memory blocks may be alternately arranged in the row direction.

As in the embodiment, base chip 320, second semiconductor chip 302, and fourth semiconductor chip 304 have the same layout, and first semiconductor chip 301 and third semiconductor chip 303 have the same layout. Accordingly, the cross-section taken along lines IV-IV in FIG. 7 is the same as the cross-section illustrated in FIG. 4. Thus, as in the embodiment, the operation blocks, which easily generate heat, are not superposed on the other operation blocks. This prevents local heat concentration and allows efficient heat dissipation. Moreover, the operation blocks and the memory blocks are close to each other in the semiconductor chips and base chip 320, reducing the travel distance for data and thus reducing the power consumption.

### 7-2. Variation 2

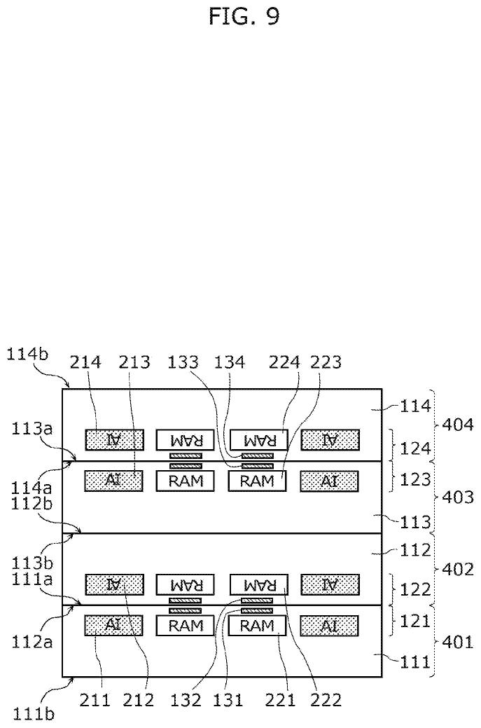

Next, Variation 2 will be described with reference to FIGS. 8 and 9. FIG. 8 is a plan view of layouts of base chip 420 and semiconductor chips in an AI module according to this variation. FIG. 9 is a cross-sectional view of a stacked state of four semiconductor chips in the AI module according to this variation. FIG. 9 illustrates a cross-section taken along lines IX-IX in FIG. 8.

As illustrated in FIG. 8, a plurality of operation blocks and a plurality of memory blocks are arranged in a striped pattern in base chip 420, first semiconductor chip 401, second semiconductor chip 402, third semiconductor chip 403, and fourth semiconductor chip 404.

In this variation, the arrangements of the plurality of operation blocks and the plurality of memory blocks in base chip 420, first semiconductor chip 401, second semiconductor chip 402, third semiconductor chip 403, and fourth semiconductor chip 404 are the same. That is, the plurality of operation blocks 211 of first semiconductor chip 401 correspond one-to-one with the plurality of operation blocks 212 of second semiconductor chip 402 and are superposed on corresponding operation blocks 212 in plan view. Similarly, the plurality of memory blocks 221 of first semiconductor chip 401 correspond one-to-one with the plurality of memory blocks 222 of second semiconductor chip 402 and are superposed on corresponding memory blocks 222 in plan view. In other words, in plan view, the operation blocks and the memory blocks are superposed on the other operation blocks and the other memory blocks, respectively.

Similarly, in third semiconductor chip 403 and fourth semiconductor chip 404, the operation blocks and the memory blocks of one chip are respectively superposed on the operation blocks and the memory blocks of the other chip. Similarly, in third semiconductor chip 403 and second semiconductor chip 402, the operation blocks and the memory blocks of one chip are respectively superposed on the operation blocks and the memory blocks of the other chip. Similarly, in base chip 420 and first semiconductor chip 401, the operation blocks and the memory blocks of one chip are respectively superposed on the operation blocks and the memory blocks of the other chip.

In this variation, the communication units are disposed at positions overlapping the memory blocks in plan view. Specifically, as illustrated in FIG. 9, memory blocks 221 overlap coiled antenna 131 in first semiconductor chip 401. The same applies to second semiconductor chip 402, third semiconductor chip 403, and fourth semiconductor chip 404. In this variation, antennas 131 to 134 and memory blocks 221 to 224 overlap each other in plan view. Note that an antenna (not illustrated) provided for base chip 420 similarly overlaps antennas 131 to 134 in plan view.

Memory blocks 221 to 224 are usually formed by repeatedly placing a predetermined pattern including wiring and storage portions. Accordingly, design changes, such as removal of the repetitive pattern only from parts overlapping antennas 131 to 134, can be easily implemented.

According to this variation, the communication units can be disposed to overlap the memory blocks. This eliminates the need to allocate dedicated regions to the communication units in plan view, reducing the size of the semiconductor chips, that is, the size of the AI module. Moreover, the use of near-field inductive coupling communication can reduce the power consumption. Moreover, as in the embodiment and Variation 1, a reduction in the travel distance for data can also reduce the power consumption.

### 7-3. Variation 3

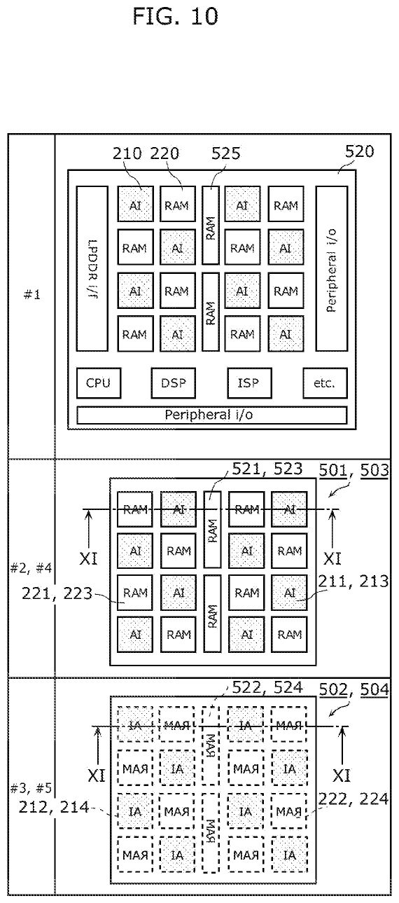

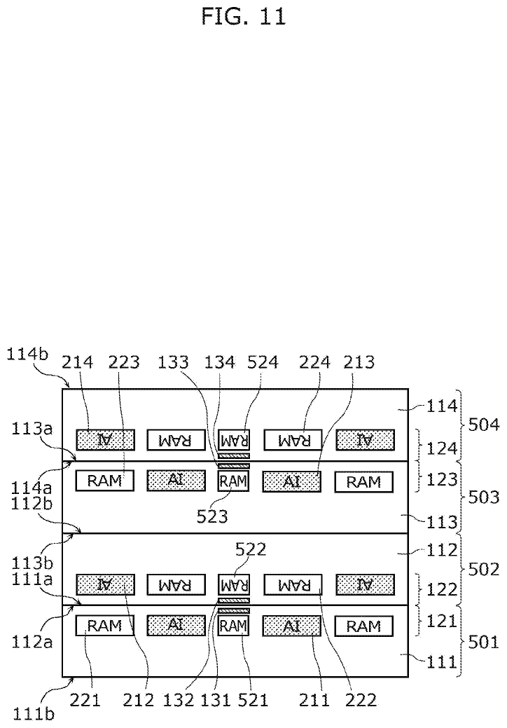

Next, Variation 3 will be described with reference to FIGS. 10 and 11. FIG. 10 is a plan view of layouts of base chip 520 and semiconductor chips in an AI module according to this variation. FIG. 11 is a cross-sectional view of a stacked state of two semiconductor chips in the AI module according to this variation. FIG. 11 illustrates a cross-section taken along lines XI-XI in FIG. 10.

As illustrated in FIG. 10, first semiconductor chip 501 includes a plurality of memory blocks 521 in addition to the configuration of first semiconductor chip 101. Note that the number of memory blocks 521 may be only one, or three or more. Memory blocks 521 are an example of fifth processing units including memory.

The plurality of memory blocks 521 are disposed in the middle of first semiconductor chip 501. In the example illustrated in FIG. 10, the plurality of memory blocks 521 are disposed in the middle, in the row direction, of an area in which 4 rows and 4 columns of operation blocks 211 and memory blocks 221 are disposed. Specifically, in plan view, the plurality of memory blocks 521 each have a rectangular shape extending in the column direction and are consecutively aligned in the column direction. Note that the plurality of memory blocks 521 may have a rectangular shape extending in the row direction and may be consecutively aligned in the row direction in the middle, in the column direction, of the area with the array of 4 rows and 4 columns. Alternatively, operation blocks 211 and memory blocks 221 may be arranged to surround memory blocks 521. Alternatively, memory blocks 521 may be disposed diagonally.

Second semiconductor chip 502 includes a plurality of memory blocks 522 in addition to the configuration of second semiconductor chip 102. Note that the number of memory blocks 522 may be only one, or three or more. Memory blocks 522 are an example of sixth processing units including memory.

The shape, number, and arrangement of the plurality of memory blocks 522 are the same as those of the plurality of memory blocks 521. The plurality of memory blocks 522 correspond one-to-one with the plurality of memory blocks 521 and are superposed on corresponding memory blocks 521 in plan view.

Third semiconductor chip 503 includes a plurality of memory blocks 523 in addition to the configuration of third semiconductor chip 103. Note that the number of memory blocks 523 may be only one, or three or more. Memory blocks 523 are an example of processing units including memory. The shape, number, and arrangement of the plurality of memory blocks 523 are the same as those of the plurality of memory blocks 521.

Fourth semiconductor chip 504 includes a plurality of memory blocks 524 in addition to the configuration of fourth semiconductor chip 104. Note that the number of memory blocks 524 may be only one, or three or more. Memory blocks 524 are an example of processing units including memory. The shape, number, and arrangement of the plurality of memory blocks 524 are the same as those of the plurality of memory blocks 521. The plurality of memory blocks 524 correspond one-to-one with the plurality of memory blocks 523 and are superposed on corresponding memory blocks 523 in plan view.

Base chip 520 includes a plurality of memory blocks 525 in addition to the configuration of base chip 20 illustrated in FIG. 3A. Note that the number of memory blocks 525 may be only one, or three or more. The shape, number, and arrangement of the plurality of memory blocks 525 are the same as those of the plurality of memory blocks 521.

In this variation, the communication units are disposed at positions overlapping memory blocks 521 to 524 in plan view. Specifically, as illustrated in FIG. 11, memory blocks 521 overlap coiled antenna 131 in first semiconductor chip 501. The same applies to second semiconductor chip 502, third semiconductor chip 503, and fourth semiconductor chip 504. In this variation, antennas 131 to 134 and memory blocks 521 to 524 overlap each other in plan view. Note that an antenna (not illustrated) provided for base chip 520 similarly overlaps antennas 131 to 134 in plan view.

Thus, similarly to Variation 2, the communication units can be disposed to overlap memory blocks 521 to 524. This eliminates the need to allocate dedicated regions to the communication units in plan view, reducing the size of the semiconductor chips, that is, the size of the AI module. Moreover, the use of near-field inductive coupling communication can reduce the power consumption. Moreover, as in the embodiment and Variation 1, a reduction in the travel distance for data can also reduce the power consumption. Moreover, in this variation, the operation blocks are not superposed on the other operation blocks in plan view as in the embodiment and Variation 1. This prevents local heat concentration and allows efficient heat dissipation.

### 7-4. Variation 4

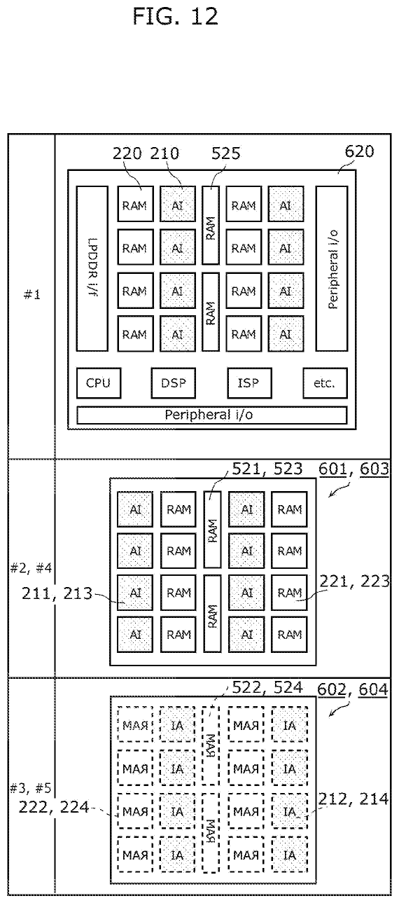

Next, Variation 4 will be described with reference to FIG. 12. FIG. 12 is a plan view of layouts of base chip 620 and semiconductor chips in an AI module according to this variation.

As illustrated in FIG. 12, first semiconductor chip 601, second semiconductor chip 602, third semiconductor chip 603, fourth semiconductor chip 604, and base chip 620 respectively have configurations obtained by adding memory blocks 521, 522, 523, 524, and 525 to first semiconductor chip 301, second semiconductor chip 302, third semiconductor chip 303, fourth semiconductor chip 304, and base chip 320, respectively, according to Variation 1. In this case, effects similar to those produced in Variation 3 can be obtained.

### 7-5. Variation 5

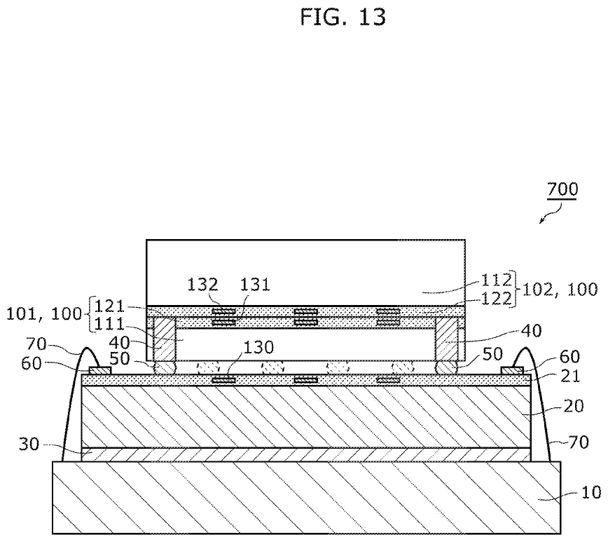

Next, Variation 5 will be described with reference to FIG. 13. FIG. 13 is a cross-sectional view of AI module 700 according to this variation.

As illustrated in FIG. 13, AI module 700 differs from AI module 1 according to the embodiment in the number of stacked semiconductor chips. AI module 700 includes two semiconductor chips 100. Note that two semiconductor chips 100 and base chip 20 may be a combination of the semiconductor chips and the base chip illustrated in Variations 1 to 4. AI module 700 illustrated in FIG. 13 is formed by, for example, omitting step S30 in the production method illustrated in FIG. 6.

### 7-6. Variation 6

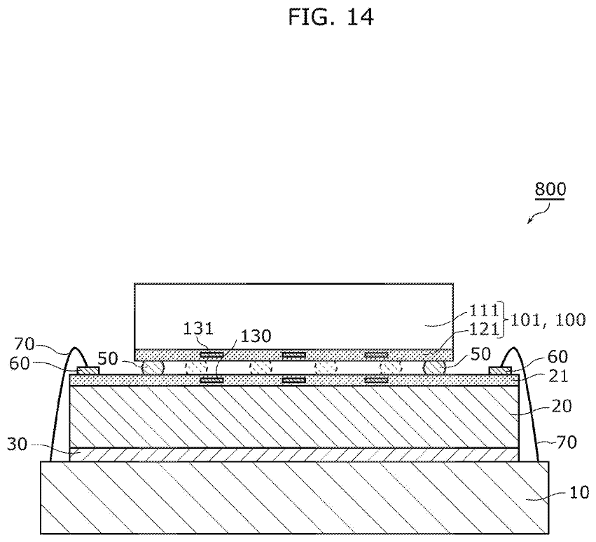

Next, Variation 6 will be described with reference to FIG. 14. FIG. 14 is a cross-sectional view of AI module 800 according to this variation.

As illustrated in FIG. 14, AI module 800 differs from AI module 1 according to the embodiment in the number of stacked semiconductor chips. AI module 800 includes only one semiconductor chip 100. Note that semiconductor chip 100 and base chip 20 may be a combination of the first semiconductor chips and the base chips illustrated in Variations 1 to 4. AI module 800 illustrated in FIG. 14 is formed by, for example, omitting steps S20 to S40 in the production method illustrated in FIG. 6.

### OTHER EMBODIMENTS

Although AI modules according to one or more aspects have been described above on the basis of the foregoing embodiments, these embodiments are not intended to limit the present disclosure. The scope of the present disclosure encompasses forms obtained by various modifications, to the embodiments, that can be conceived by those skilled in the art and forms obtained by combining elements in different embodiments without departing from the spirit of the present disclosure.

For example, an AI module according to one aspect of the present disclosure does not need to include a base chip and an interposer. The AI module may be one semiconductor chip itself. Alternatively, the AI module may be a base chip itself and does not need to include semiconductor chips stacked on the base chip.

The numbers and arrangements of operation blocks and memory blocks provided for semiconductor chips are not limited to those illustrated in the embodiment and the variations. The number of the operation blocks and the number of the memory blocks may differ from each other. The shape of the operation blocks and the shape of the memory blocks may differ from each other. Moreover, the operation blocks and the memory blocks do not need to be square and may be polygonal, such as rectangular.

Moreover, for example, the arrangements of the operation blocks and the memory blocks in the first semiconductor chips and the arrangements of the operation blocks and the memory blocks in the third semiconductor chips may differ from each other. Moreover, the arrangements of the operation blocks and the memory blocks in the second semiconductor chips and the arrangements of the operation blocks and the memory blocks in the fourth semiconductor chips may differ from each other. For example, first semiconductor chip 101 and second semiconductor chip 102 according to the embodiment may be combined with the third semiconductor chip and the fourth semiconductor chip according to one of Variations 1 to 4.

Moreover, for example, the communication units include the coiled antennas that can be inductively coupled in the above-described examples, although not limited thereto. The communication units may conduct communications using a wired connection through the through vias.

Moreover, various modifications, substitutions, additions, omissions, and the like can be made to the embodiments above within the scope of the claims or equivalents thereof.

### INDUSTRIAL APPLICABILITY

The present disclosure can be used as AI modules capable of performing AI-based operations with low power consumption, and can be used for, for example, various electrical appliances, computing devices, and the like.

### INDUSTRIAL APPLICABILITY

The present disclosure can be used as AI modules capable of performing AI-based operations with low power consumption, and can be used for, for example, various electrical appliances, computing devices, and the like.

1. An artificial intelligence (AI) module comprising:
a first semiconductor chip, wherein
the first semiconductor chip includes:
a plurality of first processing units each of which performs a predetermined operation; and
a plurality of second processing units each including memory, and
the plurality of first processing units and the plurality of second processing units are arranged in a checkered pattern or in a striped pattern in plan view.

2. The AI module according to claim 1, wherein
the plurality of first processing units each perform the predetermined operation based on a machine learning model.

3. The AI module according to claim 1, further comprising:
a second semiconductor chip stacked on the first semiconductor chip, wherein
the second semiconductor chip includes:
a plurality of third processing units each of which performs a predetermined operation; and
a plurality of fourth processing units each including memory, and
the plurality of third processing units and the plurality of fourth processing units are arranged in a checkered pattern or in a striped pattern in plan view.

4. The AI module according to claim 3, wherein
the plurality of third processing units each perform the predetermined operation based on a machine learning model.

5. The AI module according to claim 3, wherein
the first semiconductor chip further includes a first communication unit, and
the second semiconductor chip further includes a second communication unit that communicates with the first communication unit.

6. The AI module according to claim 5, wherein
the first communication unit and the second communication unit each include an antenna having a coil shape.

7. The AI module according to claim 6, wherein
the first communication unit and the second communication unit communicate with each other through the antenna of the first communication unit and the antenna of the second communication unit being inductively coupled.

8. The AI module according to claim 5, wherein
the plurality of first processing units correspond one-to-one with the plurality of third processing units and overlap the corresponding third processing units in plan view, and
the plurality of second processing units correspond one-to-one with the plurality of fourth processing units and overlap the corresponding fourth processing units in plan view.

9. The AI module according to claim 8, wherein
the first communication unit overlaps one of the plurality of second processing units in plan view, or
the second communication unit overlaps one of the plurality of fourth processing units in plan view.

10. The AI module according to claim 5, wherein
the plurality of first processing units correspond one-to-one with the plurality of fourth processing units and overlap the corresponding fourth processing units in plan view, and
the plurality of second processing units correspond one-to-one with the plurality of third processing units and overlap the corresponding third processing units in plan view.

11. The AI module according to claim 5, wherein
the first semiconductor chip further includes one or more fifth processing units each including memory,
the second semiconductor chip further includes one or more sixth processing units each including memory, and
the one or more fifth processing units correspond one-to-one with the one or more sixth processing units and overlap the corresponding sixth processing units in plan view.

12. The AI module according to claim 11, wherein
the first communication unit overlaps one of the one or more fifth processing units in plan view, and
the second communication unit overlaps one of the one or more sixth processing units in plan view.

13. The AI module according to claim 3, wherein
the first semiconductor chip further includes a first semiconductor substrate including a first main surface and a second main surface that face opposite directions,
the plurality of first processing units and the plurality of second processing units are disposed at positions closer to the first main surface of the first semiconductor substrate than to the second main surface,
the second semiconductor chip further includes a second semiconductor substrate including a third main surface and a fourth main surface that face opposite directions,
the plurality of third processing units and the plurality of fourth processing units are disposed at positions closer to the third main surface of the second semiconductor substrate than to the fourth main surface, and
the first semiconductor chip and the second semiconductor chip are stacked such that the first main surface and the third main surface face each other.

14. The AI module according to claim 13, further comprising:
a third semiconductor chip stacked on the second semiconductor chip; and
a fourth semiconductor chip stacked on the third semiconductor chip, wherein
the third semiconductor chip includes:
a third semiconductor substrate including a fifth main surface and a sixth main surface that face opposite directions;
a plurality of seventh processing units each of which performs a predetermined operation; and
a plurality of eighth processing units each including memory,
the plurality of seventh processing units and the plurality of eighth processing units are disposed at positions closer to the fifth main surface of the third semiconductor substrate than to the sixth main surface, and are arranged in a checkered pattern or in a striped pattern in plan view,
the fourth semiconductor chip includes:
a fourth semiconductor substrate including a seventh main surface and an eighth main surface that face opposite directions;
a plurality of ninth processing units each of which performs a predetermined operation; and
a plurality of tenth processing units each including memory,
the plurality of ninth processing units and the plurality of tenth processing units are disposed at positions closer to the seventh main surface of the fourth semiconductor substrate than to the eighth main surface, and are arranged in a checkered pattern or in a striped pattern in plan view,
the third semiconductor chip and the fourth semiconductor chip are stacked such that the fifth main surface and the seventh main surface face each other, and
the second semiconductor chip and the third semiconductor chip are stacked such that the fourth main surface and the sixth main surface face each other.

15. The AI module according to claim 3, further comprising:
a through via for supplying power to the second semiconductor chip, the through via passing through the first semiconductor chip.
